(19) United States
(12) Patent Application Publication
(10) Pub. No.: US 2024/0159797 A1
(43) Pub. Date: May 16, 2024

(54) OPTICALLY-IMPLEMENTED ANALOG MUX ACCESSORY FOR A TEST AND MEASUREMENT INSTRUMENT

(71) Applicant: Tektronix, Inc., Beaverton, OR (US)

(72) Inventors: Daniel G. Knierim, Beaverton, OR (US); Shane A. Hazzard, Portland, OR (US); Scott T. Harrison, Beaverton, OR (US); Timothy E. Bieber, Portland, OR (US)

(21) Appl. No.: 18/511,977

(22) Filed: Nov. 16, 2023

Related U.S. Application Data
(60) Provisional application No. 63/426,000, filed on Nov. 16, 2022.
(60) Provisional application No. 63/452,571, filed on Mar. 16, 2023.

(51) Int. Cl. G01R 1/20

(52) U.S. Cl. CPC G01R 1/20; G02B 6/12

(57) ABSTRACT

A test and measurement system includes one or more remote heads, each of the one or more remote heads configured to be coupled to a respective device under test (DUT) to receive an electrical test signal from the DUT and each of the one or more remote heads including an electrical-to-optical (EOM) configured to convert the received electrical test signal into an optical test signal. Optical interconnection circuitry receives the optical test signal from the EOM of the one or more remote heads and, in response to control signals, selects one of the optical test signals to be provided to a test and measurement system. The optical interconnection circuitry further converts the selected optical test signal into an electrical test signal to be supplied to a test port of the test and measurement instrument. Methods are also described.

### REFERENCE TO RELATED APPLICATIONS

This disclosure claims benefit of U.S. Provisional Application No. 63/426,000, titled “OPTICALLY-IMPLEMENTED ANALOG MUX ACCESSORY FOR A TEST AND MEASUREMENT INSTRUMENT,” filed on Nov. 16, 2022, and benefit of U.S. Provisional Application No. 63/452,571, titled “ANALOG-OVER-OPTICAL REMOTE HEAD FOR PROBING,” filed on Mar. 16, 2023, the disclosures of which are incorporated herein by reference in their entirety.

### TECHNICAL FIELD

This disclosure is directed generally to systems and methods related to test and measurement systems, and, in particular, to test and measurement systems including optical interconnections for measuring multiple signals from a device under test (DUT).

### BACKGROUND OF THE INVENTION

Many DUTs include a multitude of similarly designed signal paths. For example, a Peripheral Component Interconnect (PCI) Express (PCIe or PCI-e) plug-in card and/or a PCIe motherboard slot commonly include up to sixteen electrical signal “lanes.” The electrical signal lanes are typically differential signal lanes, meaning that one differential lane requires two electrical measurement ports to fully measure the differential signal of the lane. Thus, to fully measure a sixteen lane PCIe device would require 32 electrical measurement ports. However, test and measurement instruments typically used to test such DUTs, such as oscilloscopes or bit error rate testers (BERTs), typically have one, two, or four input ports. Although some oscilloscopes include eight input channels or ports, high performance instruments typically have fewer input channels due to the increased hardware costs associated with each channel. Physical channel density limitations also can keep channel count low for thermal and throughput reasons. For this reason, it is typical that a test and measurement instrument configuration will be connected to only a subset of the electrical signal lanes to be tested.

Since only a subset of lanes are coupled to the test and measurement instrument, if a user wishes to test all of the signal lanes, the user must manually move a connection between the test and measurement instrument and the DUT, e.g., a test cable or probe, from each lane to lane manually. Manually moving the cable or probe is an error-prone and very time and labor-intensive process. Alternatively, such as in a two-channel test and measurement environment, a radio frequency (RF) switch can be built and maintained to allow for automation for testing all signal lanes of the DUT. However, identifying a suitable switch and correctly de-embedding the impact of the switch from the signal path, which is performed manually, are difficult at higher frequencies. Because of this, many users do not trust the switches can be de-embedded without significant errors, especially above 25 GHz. De-embedding or “calibrating” for the impact of the switch, or other component, on a signal path is the compensation for negative effects the switch has on signals propagating through the signal path. In addition to the need for de-embedding, an RF switch matrix is physically large, which makes the RF switch matrix solution particularly unattractive to users having limited physical area for testing.

When testing a DUT, customers also must locate the DUT as close as possible to inputs of the test and measurement instrument to minimize the degradation of signal integrity (i.e., signal distortion). When using RF cables that support communication of signals at greater than 60 GHz, the cables are expensive, and have significant insertion loss (>6 dB/meter). Insertion loss is the energy loss of a signal as it propagates along a cable, and the insertion loss limits the maximum length of a cable between the DUT and the test and measurement instrument. Current approaches to compensating for adverse effects of cables utilize de-embedding, which requires additional expensive equipment such as a vector network analyzer (VNA) along with skilled technicians/engineers, specialized software like serial data link analysis (SDLA) software, and the time required to achieve the required de-embedding. Moreover, this de-embedding approach has limitations. For example, the de-embedding may result in a reduced signal-to-noise ratio for a signal propagating through the cable, which affects measurement accuracy of the signal.

Examples of the present disclosure address these and other deficiencies of the prior art.

### BRIEF DESCRIPTION OF THE DRAWINGS

Aspects, features and advantages of examples of the present disclosure will become apparent from the following description of examples in reference to the appended drawings in which:

FIG. 1 is a block diagram of a test and measurement system including multiple remote heads that each include an electrical-to-optical modulator optically coupled through optical multiplexing circuitry to the test and measurement system, according to some examples of the present disclosure.

FIG. 2 is a block diagram of a test and measurement system including multiple remote heads each including an RF switch and electrical-to-optical modulator that is optically coupled through optical interconnection circuitry to one of two synchronized test and measurement instruments to enable pseudo-differential measurements, according to some examples of the present disclosure.

FIG. 3 is a block diagram of a test and measurement system including multiple remote heads each including an RF switch and electrical-to-optical modulator that is optically coupled through optical interconnection circuitry to respective test port of a test and measurement instrument to enable pseudo-differential measurements, according to some examples of the present disclosure.

FIG. 4 is a block diagram of a test and measurement instrument including a remote head coupled to receive single-ended electrical test signals from DUTs and including electrical-to-optical modulators and optical multiplexing circuitry to provide a corresponding optical test signal over optical interconnection circuitry to a test and measurement instrument according to some examples of the present disclosure.

FIG. 5 is a block diagram of a test and measurement instrument including a remote head coupled to receive differential electrical test signals from a DUT and including electrical-to-optical modulators and optical multiplexing circuitry to provide optical test signals over optical interconnection circuitry to a test and measurement instrument according to some examples of the present disclosure.

FIG. 6 is a block diagram of a test and measurement instrument including a remote head and feedback compensation circuitry that compensates for variations in optical interconnection circuitry that may adversely affect characteristics of an electrical test signal provided to a test and measurement instrument according to some examples of the present disclosure.

FIG. 7 is a block diagram of a test and measurement instrument including a remote head and feedforward compensation circuitry that compensates for variations in optical interconnection circuitry that may adversely affect characteristics of an electrical test signal provided on a test port of a test and measurement instrument according to some examples of the present disclosure.

### DESCRIPTION

Embodiments of the present disclosure utilize one or more remote heads that are coupled through multiplexing circuitry and optical interconnection circuitry to a test and measurement system. A remote head may contain front-end circuitry, such as amplification circuitry, of a test channel of a test and measurement instrument. This structure including remote heads and optical interconnection circuitry reduces the need for de-embedding to compensate for signal loss in cables by enabling remote heads to be placed near each DUT being tested. Insertion loss of cables is also reduced through optical interconnections to the test and measurement system. The structure also enables the test and measurement system to remain stationary, with coupling to the system through larger distances being possible through the optical interconnections between the remote head(s) and the test and measurement system. The conversion of an electrical signal from the DUT to an optical signal allows positioning the DUT at much greater distances from the test and measurement system while preserving the signal-to-noise ratio of the electrical signal.

In embodiments of the present disclosure, the distant or remote location(s) of the remote head(s) also mean that test and measurement systems according to embodiments of the present disclosure do not need to occupy significant space on benchtop on which the test and measurement system is located in an attempt to position an input of the system as close as possible to a test point of a DUT. Utilization of remote heads also enables a closer connection between test points of the DUT and front-end circuitry for processing signals from these test points. This is true even for direct connections between the test points on the DUT and inputs of the test and measurement system where the DUT is positioned on the benchtop proximate the system. Furthermore, in test and measurement systems according to embodiments of the present disclosure, multiplexing of signals of the DUT(s) coupled to the one or more remote probe heads, either before or after the electrical-to-optical modulation or conversion, simplifies setup by a customer, and enables the customer to utilize one channel of a test and measurement system without having to reconfigure the setup for measuring multiple DUT signals.

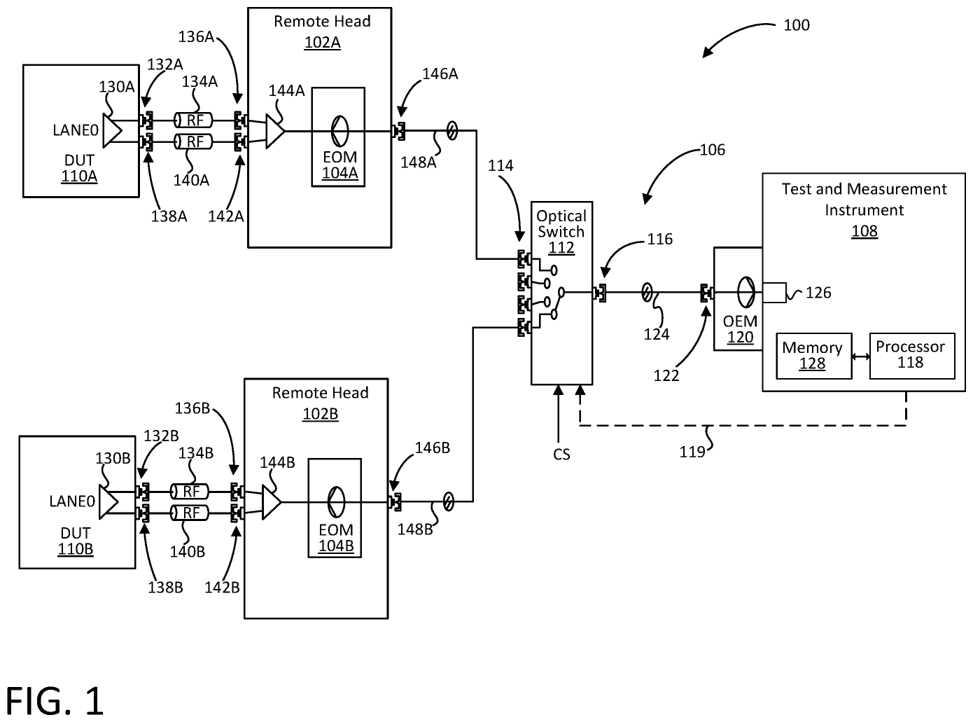

FIG. 1 is a block diagram of a test and measurement system 100 including multiple remote heads 102A, 102B that each include an electrical-to-optical modulator (EOM) 104A, 104B optically coupled through optical interconnection circuitry 106 to a test and measurement instrument 108, according to some examples of the present disclosure. Each EOM 104A, 104B modulates or converts an electrical test signal from a corresponding device under test (DUT) 110A, 110B into an optical test signal for communication to the test and measurement instrument 108, which is physically located remotely or at a distance from the remote heads 102A, 102B. The DUTs 110A, 110B each of may be a test board, for example, and is connected through a respective one of the remote heads 102A, 102B and optical interconnection circuitry 106 to the test and measurement instrument 108. The optical interconnection circuitry 106 includes an optical switch 112, which may also be referred to as a data selector, and which includes a number of optical input ports 114 and an optical output port 116. Each of the multiple optical input ports 114 receives an optical signal corresponding to an electrical test signal from one of the DUTs 110A, 110B.

Electrical control signals CS are applied to the optical switch 112, and in response to the CS signals, the optical switch supplies an optical signal on a selected one of the optical input ports 114 to the optical output port 116. In this way, the optical switch 112 functions as a multiplexer to enable a user, through the CS signals, to select any of the test signals being provided from the DUTs 110A, 110B for testing. This structure minimizes the required number of connections between the test and measurement instrument 108 and the DUTs 110A, 110B. Although two DUTs 110A, 110B are shown in the example embodiment of FIG. 1, additional DUTs may be coupled to the system 100 for testing. For example, in the system 100 the optical switch 112 includes four optical input ports 114, and thus a differential signal from one of four DUTs, or one of four differential signals from a single DUT, could be coupled through the optical switch 112 to the test and measurement instrument 108.

The control signals CS applied to optical switch 112 may be provided by circuitry (not shown) that is external to the test and measurement system 100, allowing a user to control the optical switch 112 through this circuitry and provide an optical signal on a selected one of the optical input ports 114 to the test and measurement instrument 108 for testing. In other example embodiments, a processor 118 of the test and measurement instrument 108 can apply the control signals CS to the optical switch 112 to select the optical signal on one of the optical input ports 114 to be provided on the optical output port 116 for testing by test and measurement instrument 108. This is represented in FIG. 1 through the dashed line 119 between the instrument 108 and the optical switch 112.

The optical interconnection circuitry 106 further includes an optical-to-electrical modulator (OEM) 120 having an optical input port 122 coupled through a suitable optical waveguide such as a fiber optic cable 124 to the optical output port 116 of the optical switch 112. The optical signal on the selected one of the input ports 114 of the optical switch 112 is provided on the output optical port 116 and propagates through the fiber optic cable 120 to the optical input port 122 of the OEM 120. The OEM 120 modulates or converts this optical signal received on the input port 122 to provide a corresponding electrical test signal. A test port 126 of the test and measurement instrument 108 is coupled to the OEM 120 to receive this electrical test signal from the EOM 120 and to provide the electrical test signal to the processor 118 and other circuitry in the test and measurement instrument for testing. The processor 118 of the test and measurement instrument 108 is coupled to a memory 128, which may store test configuration data for generation of the CS signals applied to the optical switch 112 to control selection of a signal from a desired one of the DUTs 110A, 110B being tested.

Each DUT 110A, 110B includes a single electrical signal lane LANE0 coupled to a corresponding differential output amplifier 130A, 130B. In some embodiment, each of the DUTs 110A, 110B may be a stand-alone device and may include one or more signal lanes or may refer to a particular output component of a DUT that itself has multiple signal lanes. A modern PCIe device, for example, may include sixteen lanes, each lane having a differential signal pair. Embodiments according to this disclosure provide the user with an ability to easily select any of the signals from such a DUT for testing while also eliminating the noise that is inevitably added by using one or more cascaded RF switches, as in present systems.

In the example embodiment of FIG. 1, each signal lane LANE0 of the DUTs 110A, 110B is a differential signal lane including a pair of differential output signals. Although the electrical signals are depicted as being differential here, single-ended electrical implementations are also possible. The output from each DUT 110A, 110B for the lane LANE0 is transmitted as the difference between the two differential output signals. Each differential output signal of the amplifier 130A, 130B is coupled to an input of the remote head 102A, 102B. More specifically, for the lane LANE0 in DUT 110A a first one of the differential output signals is coupled from an RF connector 132A on the DUT through an RF cable 134A to an RF connector 136A on the remote head 102A. The RF cable 134A may be a coaxial cable to minimize signal loss between the DUT 110A and the remote head 102A, for example. Likewise, the second differential output signal from Lane 0 is coupled from an RF connector 138A on the DUT 110A through an RF cable 140A to an RF connector 142A on the remote head 102A. Similarly, the amplifier 130B of DUT 110B is coupled through RF connectors 132B, 138B and RF cables 134B, 140B to RF connectors 136B, 142B on the remote head 102B.

A differential pre-amplifier 144A, 144B in each remote head 102A, 102B has a pair of inputs coupled to the corresponding RF connectors 136A, 142A and 136B, 142B on the remote head. Each pre-amplifier 144A, 144B generates an electrical amplified output signal based on the difference between the differential output signals from lane LANE0 the DUT 110A, 110B, and the amplified output signal is supplied to the electrical-to-optical modulator (EOM) 104A, 104B in the remote head 102A, 102B. In some embodiments, the amplifiers 144A, 144B may be eliminated and the electrical signals from the DUTs 110A, 110B may drive the EOMs 104A, 104B directly. Including the pre-amplifiers 144A, 144B and/or EOMs 104A, 104B as close as possible to the test signal of the corresponding DUT 110A, 110B increases the signal-to-noise ratio of the test signal in the testing system 100, by amplifying and/or modulating the test signal as close to its source (i.e., the corresponding DUT) as possible. In the remote head 102A, 102B, each EOM 104A, 104B modulates or converts the amplified electrical output signal from the pre-amplifier 144A, 144B to an optical signal that is provided on an optical output port 146A, 146B of the remote head 102A, 102B. The optical signals on output ports 146A, 146B of the remote heads 102A, 102B are supplied through suitable fiber optic cables 148A, 148B to a respective one of the optical input ports 114 of the optical switch 112.

In operation, each DUT 110A, 110B generates test signals to be measured by the test and measurement instrument 108 in form of the differential output signals of lane LANE0 provided by the differential amplifier 130A, 130B in the DUT. These differential output signals from each DUT 110A, 110B are supplied through the RF cables 134A, 134B and 140A, 140B to the corresponding remote head 102A, 102B. Each remote head 102A, 102B may be positioned proximate the DUT 110A, 110B coupled to the remote head. This reduces the lengths of RF cables 134A, 134B and 140A, 140B required to couple the remote head to the DUT 110A, 110B, and in this way reduces signal loss and improves signal integrity of test signals received at each remote head.

In each remote head 102A, 102B, the corresponding pre-amplifier 144A, 144B generates the electrical amplified output signal based on the differential output signals received on the RF connectors 136A, 136B and 142A, 142B of the remote head and each EOM 104A, 104B modulates or converts the amplified electrical output signal to an optical signal that is provided on an optical output port 146A, 146B of the remote head 102A, 102B. In this way, the test signals of the DUTs 110A, 110B are converted into optical signals before being communicated to the test and measurement instrument 108 for testing. Optical signals may be communicated over much greater distances than electrical signals without experiencing adverse effects or distortion that may impair the ability of the test and measurement instrument 108 to reliably measure the test signals. This structure reduces the need for de-embedding or calibration of components contained in the connection path between the remote heads 102A, 102B and the test and measurement instrument 108.

The optical signal from the EOM 104A, 104B provided on optical output port 146A, 146B of the remote head 102A, 102B is supplied through the optical interconnection circuitry 106 to the test port 126 of the test and measurement instrument 108. Control signals CS are applied to the optical switch 112 of the circuitry 106, such as through an external circuit in response to user input, to select which test signal is supplied to the test port 126 for testing. The optical switch 112 performs a multiplexing function and supplies an optical signal on one of several optical input ports 114 to the optical output port 116, which is to be supplied to the test and measurement instrument 108. The optical signal provided on the output port 116 of the optical switch 112 is supplied through the fiber optic cable 124 to the optical input port 122 of the OEM 120 which, in turn, modulates or converts the optical signal into the electrical test signal that is supplied to the test port 126 of the test and measurement instrument 108. In this structure, the test signal from the selected DUT 110A, 110B is converted to an optical signal in the remote head 102A, 102B and this optical signal is then communicated to the OEM 120 that is coupled to the test port of the test and measurement instrument 108.

The distance between the remote head 102A, 102B and the corresponding DUT 110A, 110B would typically be much less than the distance between each remote head and the test and measurement instrument 108. Thus, the structure of the system 100 communicates the electrical test signal of the DUT 110A, 110B to the remote head 102A, 102B positioned near the DUT, and this test signal is then converted into an optical signal for communication over the much greater distance between the remote head and the test and measurement instrument 108. The optical signal is not converted back into an electrical test signal until the optical signal reaches the EOM 120, which is directly connected to the test port 126 of the instrument 108. This reduces signal degradation and reduces the need for de-embedding to be done in propagating the test signal from the remote head 102A, 102B to the test and measurement instrument 108. The test and measurement system 100 also enables a user to select, via the CS signals supplied to the optical switch 112, the desired signals from the DUTs 110A, 110B without needing to manually move cables or probe heads, which are an error-prone and time and labor-intensive processes.

One skilled in the art will understand suitable structures that may be utilized for the components of the optical interconnection circuitry 106 and the EOMs 104A and 104B contained in the remote heads 102A, 102B. For example, the OEM 120 may include a photodiode for converting the received optical signal from the optical switch 112 into the electrical test signal supplied to the test port 126 of the test and measurement instrument 108. In some embodiments of the present disclosure, each of the EOMs 104A, 104B may be a Mach-Zehnder modulator (MZM) that utilizes the electrical signal of the corresponding DUT 110A, 110B to modulate an optical signal, which would typically be provided by laser that may be considered part of the MZM. Embodiments of the present disclosure are not limited, however, to utilizing Mach-Zehnder modulators for the EOMs 104A, 104B. The theory and operation of Mach-Zehnder modulators will be understood by those skilled in the art and thus will not be described in detail in the present description. Regardless of the specific structure of each EOM 104A, 104B, the EOM functions to modulate some characteristic of an optical carrier signal with an electrical signal, such as an electrical RF test signal. Similarly for the OEM 120, regardless of the specific structure of the OEM, the OEM functions to recover an original electrical signal from a received modulated optical carrier signal.

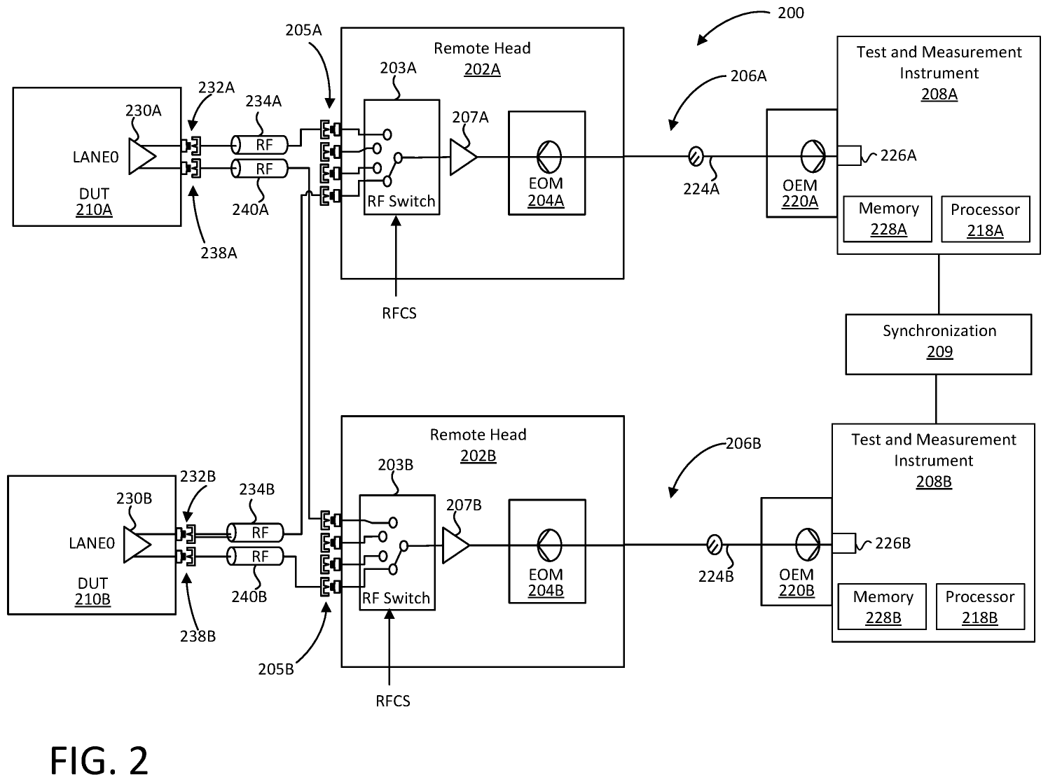

FIG. 2 is a block diagram illustrating an alternative test and measurement system 200 according to some embodiments of the present disclosure. In the test and measurement system 200, many of the components are the same or similar to components in the test and measurement system 100 discussed above with respect to FIG. 1. Accordingly, these same or similar components in the test and measurement system 200 have been given the same two hundred level number as the corresponding one hundred level component in the test and measurement system 100 of FIG. 1, and will not again be discussed in detail with respect to FIG. 2.

The test and measurement system 200 includes multiple remote heads 202A, 202B, each remote head including an RF switch 203A, 203B and an electrical-to-optical modulator (EOM) 204A, 204B that is optically coupled through optical interconnection circuitry 206A, 206B to one of two synchronized test and measurement instruments 208A, 208B. This structure of the test and measurement system 200 enables pseudo-differential measurements to be performed on differential signals from DUTs 210A, 210B, as will now be described in more detail.

Differently than in the test and measurement system 100 of FIG. 1, each of the remote heads 202A, 202B in the test and measurement system 200 of FIG. 2 includes an RF switch 203A, 203B, which operate in combination to provide multiplexing functionality of differential output signals from the DUTs 210A, 210B. The RF switches 203A, 203B provide signal switching functionality instead of the optical switch 112 in the test and measurement system 100. Each RF switch 203A, 203B receives RF control signals RFCS to select one of multiple RF input ports 205A, 205B to be coupled to an RF output port. The RF output port of each RF switch 203A, 203B is coupled to corresponding single-ended pre-amplifier 207A, 207B in the remote heads 202A, 202B. Each pre-amplifier 207A, 207B amplifies the corresponding RF signal received from the RF switch 203A, 203B to improve the signal-to-noise ratio of this RF signal, and the amplified RF signal from each pre-amplifier is supplied to the corresponding EOM 204A, 204B in the remote head 202A, 202B.

The RF input ports 205A, 205B of the RF switches 203A, 203B are coupled to the differential output amplifiers 230A, 230B of the DUTs 210A, 210B so that the differential output signal from one of these differential output amplifiers may be selected for testing through RFCS signals applied to the RF switches. For example, when the RF switches 203A, 203B are in the state shown in FIG. 2, the differential output signal from the differential output amplifier 230B of the DUT 210B is selected. A first one of the differential output signals from the differential output amplifier 230B is supplied through the RF switch 203A to the pre-amplifier 207A in remote head 202A while the second one of the differential output signals from the differential output amplifier 230B is supplied through RF switch 203B to the pre-amplifier 207B in remote head 202B. The RFCS signals may alternatively be applied to the RF switches 203A, 203B to select the differential output signals from the differential output amplifier 230A of the DUT 210A.

The EOMs 204A, 204B operate in the same way as described above for the components 104A, 104B to modulate an optical signal with the RF signal from the corresponding amplifier 207A, 207B. Each of these modulated optical signals from the EOMs 204A, 204B is thereafter communicated through the corresponding optical interconnection circuitry 206A, 206B to the corresponding test and measurement instrument 208A, 208B. The optical interconnection circuitry 206A, 206B includes the fiber optic cables 224A, 224B and OEMs 220A, 220B that function in the same way as the corresponding components described above for the system 100 of FIG. 1. The optical interconnection circuitry 206A, 206B also provides the same advantages in the system 200 as discussed above for the system 100, namely, to reduce signal degradation and the need for de-embedding to be done in propagating test signals from the remote heads 202A, 202B to the test and measurement instruments 208A, 208B.

In the same was as described above for the system 100 of FIG. 1, the RFCS signals applied to the RF switches 203A, 203B may be provided by circuitry (not shown) that is external to the test and measurement system 200. This allows a user to control the RFCS switches to select the differential output signal from one of the DUTs 210A, 210B for testing. Alternatively, the processor 218A, 218B in one of the test and measurement instruments 208A, 208B can apply, in response to user input supplied through the instrument, the RFCS signals to the RF switches 203A, 203B to select the desired one of the differential output signals.

In operation, a user provides input to generate the RFCS signal to select the differential output signal from the desired one of the DUTs 210A, 210B to be tested. In response to the RFCS signals, one signal of the selected differential output signal is supplied through the corresponding remote head 202A and optical interconnection circuitry 206A to the instrument 208A. The other signal of the selected differential output signal is supplied through the corresponding remote head 202B and optical interconnection circuitry 206B to the instrument 208B. The OEMs 220A, 220B convert the received optical signals into corresponding electrical test signals, each test and measurement instrument 208A, 208B receiving one electrical test signal on the corresponding test port 226A, 226B.

A synchronization circuit 209 is coupled to the test and measurement instruments 208A, 208B to synchronize capture of electrical test signals received on the test ports 226A, 226B of these two separate instruments. The synchronization circuit 209 controls the test and measurement instruments 208A, 208B to synchronize sample clocks used in each instrument to capture and digitize the electrical test signals on the test ports 222A. 226B. The synchronization circuit 209 may, for example, implement the UltraSync multi-unit time synchronization bus by Tektronix, Inc of Beaverton, Oregon. to provide the required synchronization of the two test and measurement instruments 208A, 208B.

The test and measurement system 200 of FIG. 2 enables pseudo-differential measurements of differential output signals from the DUTs 210A, 210B. The system 200 routes one signal of a differential output signal from one of DUTs 210A, 210B to one channel (e.g., test port 226A) of a first test and measurement instrument 208A and routes the second signal of the differential output signal to one channel (e.g., test port 226B) of the second test and measurement instrument 208B. The synchronization circuit 209 synchronizes the two instruments 208A, 208B to synchronize capture of the two signals of the differential output signal being tested. The structure of the system 200 also requires the use of only one test port 226A, 226B on each of the test and measurement instruments 208A, 208B, and may be advantageously utilized in situations where ports available or present on the test and measurements instruments are limited.

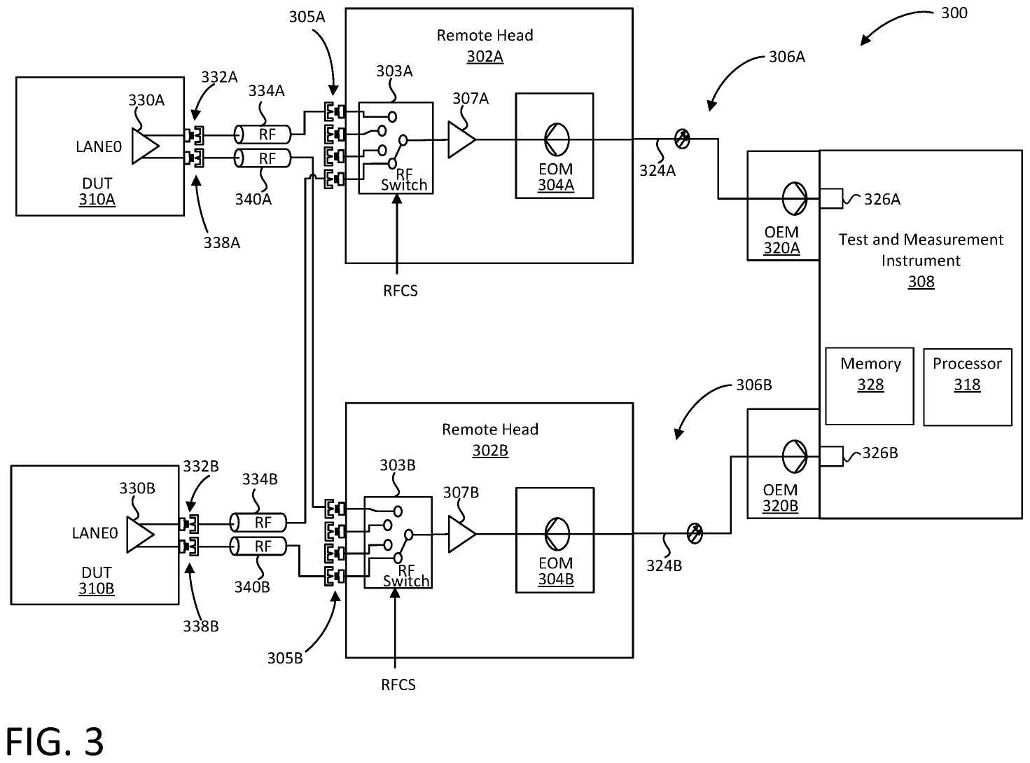

FIG. 3 is a block diagram illustrating another alternative test and measurement system 300 according to some embodiments of the present disclosure. In the test and measurement system 300, many of the components are the same or similar to components in the test and measurement systems 100 and 20 discussed above with respect to FIGS. 1 and 2. Accordingly, these same or similar components in the test and measurement system 300 have been given the same three hundred level number as the corresponding one or two hundred level component in the test and measurement systems 100 and 200 of FIGS. 1 and 2, and will not again be discussed in detail with respect to FIG. 2.

The test and measurement system 300 of FIG. 3 includes multiple remote heads 302A, 302B, each including an RF switch 303A, 303B and electrical-to-optical modulator 304A, 304B that is optically coupled through optical interconnection circuitry 306A, 306B to a respective test port 226A, 226B of a test and measurement instrument 308. In contrast to system 200 of FIG. 2, the test and measurement system 300 includes the single test and measurement instrument 308 compared to the two instruments 208A, 208B and synchronization circuit 209 in the system 200. The operation of the test and measurement system 300 will be understood from the above description of the systems 100 and 200 and thus this operation will not again be described with reference to FIG. 3.

In the system 300, the remote heads 302A, 302B enable a user to select, through the RFCS signals, the desired one of the differential output signals from the DUTs 310A, 310B for coupling to the test ports 326A, 326B of the test and measurement instrument 308. Each of the first and second differential output signals from the selected DUT 310A, 310B is in this way routed to a different channel of the test and measurement instrument 308, where each test port 326A, 362B is an input port to a channel of the test and measurement instrument. This enables pseudo-differential measurements of the differential output signals from the DUTs 310A, 310B by the test and measurement instrument 308 and does not require the external synchronization circuit 209 of FIG. 2.

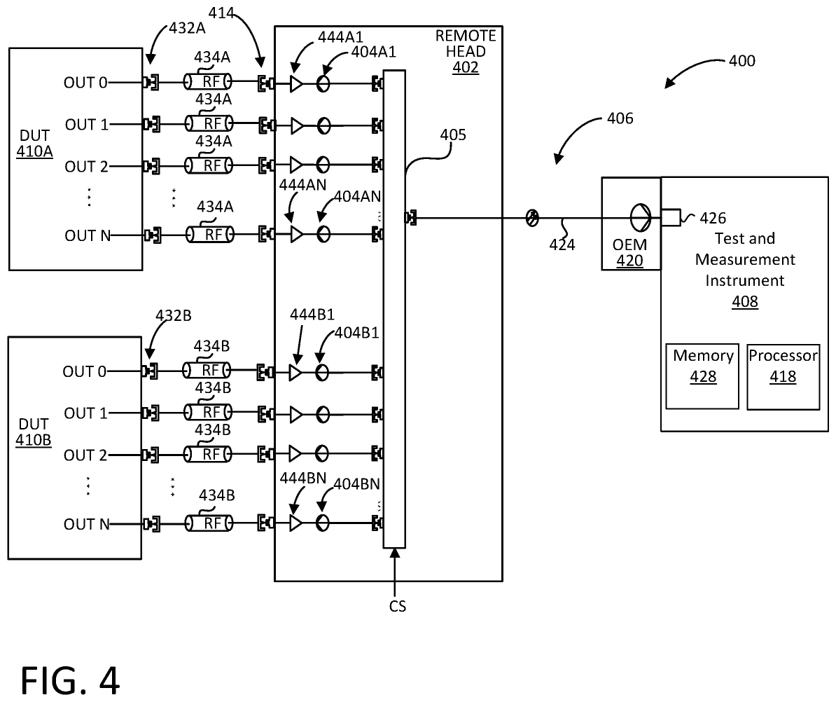

FIG. 4 is a block diagram of a test and measurement system 400 including a remote head 402 containing a number of electrical-to-optical modulators (EOM) 404A1-404AN and 404B1-404BN coupled through an optical switch or optical multiplexer 405 and optical interconnection circuitry 406 to a test and measurement instrument 408 for testing of single-ended electrical test signals received from outputs OUT1-OUTN of DUTs 410A, 410B according to some examples of the present disclosure. The remote head 404 provides optical multiplexing of test signals from the DUTs 410A, 410B and optical transmission of a selected one of these test signals is provide over the optical interconnection circuitry 406 to the test and measurement instrument 408. In the system 400, the electrical test signals of the DUTs 410A, 410B provided on outputs OUT0-OUTN are converted into corresponding optical test signals by the EOMs 404A1-404AN and 404B1-404BN in the remote test head 402. Controls signal CS are applied to the optical multiplexer 405 to select one of the optical test signals from the EOMs 404A1-404AN and 404B1-404BN and this selected optical test signal is communicated over a fiber optic cable 424 and OEM 420 forming the optical interconnection circuitry 406 to the test and measurement instrument 408.

The remote head 402 may optionally include amplifiers 444A1-444AN and 444B1-444BN for amplifying the electrical test signal received on the outputs OUT1-OUTN from the DUTs 410A, 410B, with the amplified electrical test signals being supplied to the EOMs 404A1-404AN, 404B1-404BN. In some embodiments, the amplifiers 444A1-444AN and 444B1-444BN may be omitted, as the EOMs 404A1-404AN and 404B1-404BN may convert the received electrical test signals to optical signals without extra amplification. In these embodiments, the electrical test signals on the outputs OUT1-OUTN of the DUTs 410A, 410B are applied through output ports 432A, 432B of the DUTs and cables 434A, 434B to input ports 414 of the remote head 402 and then directly to the EOMs 404A1-404AN, 404B1-404BN in the remote head.

The structure of the system 400 enables 2N single-ended electrical test signals from DUTs 410A, 410B to be tested using a single test port 426 of the test and measurement instrument 408. These electrical test signals are converted into optical signals before being communicated to the test and measurement instrument 408, enabling communication over much greater distances than electrical signals without experiencing adverse effects or distortion that may impair the ability of the test and measurement instrument 408 to reliably measure the test signals. In some embodiments, the components of the remote head 402 are formed in a silicon photonics integrated circuit which integrates the electrical and optical components of the remote head. The remainder of the test system 400 not specifically discussed operates as described above with reference to previously described embodiments.

Although the test system 400 of FIG. 4 illustrates electronic test signals originating from two DUTs 410A, 410B, the remote head 402 may be coupled to only a single DUT, or any number of DUTs. In other words, the input ports 414 may be coupled to electric test signals from any source.

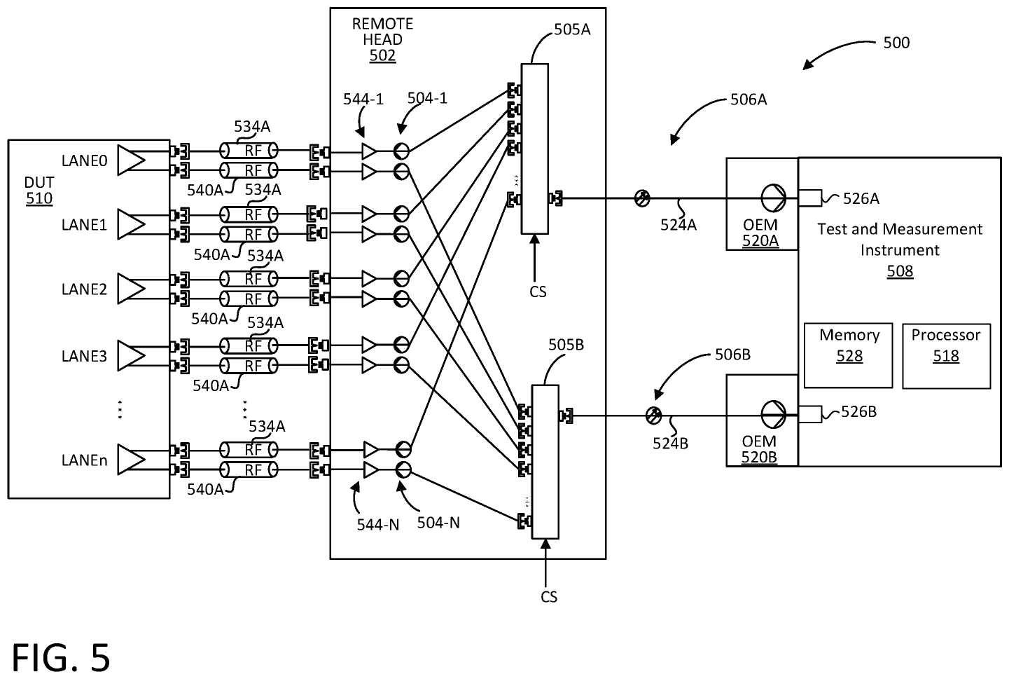

FIG. 5 is a block diagram of a test and measurement instrument 500 including a remote head 502 containing a number of electrical-to-optical modulators (EOM) 504-1-504-N coupled through optical switches or multiplexers 505A, 505B and optical interconnection circuitry 506A, 506B to a test and measurement instrument 508 for testing of differential electrical test signals received from lanes LANE0-LANEN of DUT 510 according to some examples of the present disclosure. In the system 500, one signal from each differential signal on lanes LANE0-LANEN of DUT 510 is coupled to a respective EOM 504 in the remote head 502. The corresponding optical test signals generated by the EOMs 504 in response to the received differential electrical test signals are applied to the optical multiplexers 505A, 505B so one optical test signal of each differential pair from each LANE of the DUT 510 is supplied to an optical input port of the optical multiplexer 505A and the other is supplied to an optical input port of the optical multiplexer 505B. This enables the optical test signals corresponding to one differential pair of electrical test signals to be provided by the optical multiplexers 505A, 505B to the optical interconnection circuitry 506A, 506B and supplied to test ports 526A, 526B of the test and measurement instrument 508. This enables the test and measurement instrument 508 to perform pseudo-differential measurements on the differential electronic test signals from the lanes LANE0-LANEN of the DUT 510, as described in more detail above with regard to the system 20 of FIG. 2. The remote head 502 may optionally include amplifiers 544-1-544-N for amplifying each of the differential electrical test signals received from the lanes LANE0-LANEN from the DUT 510, with the amplified differential electrical test signal being supplied to the EOMs 504-1-504-N.

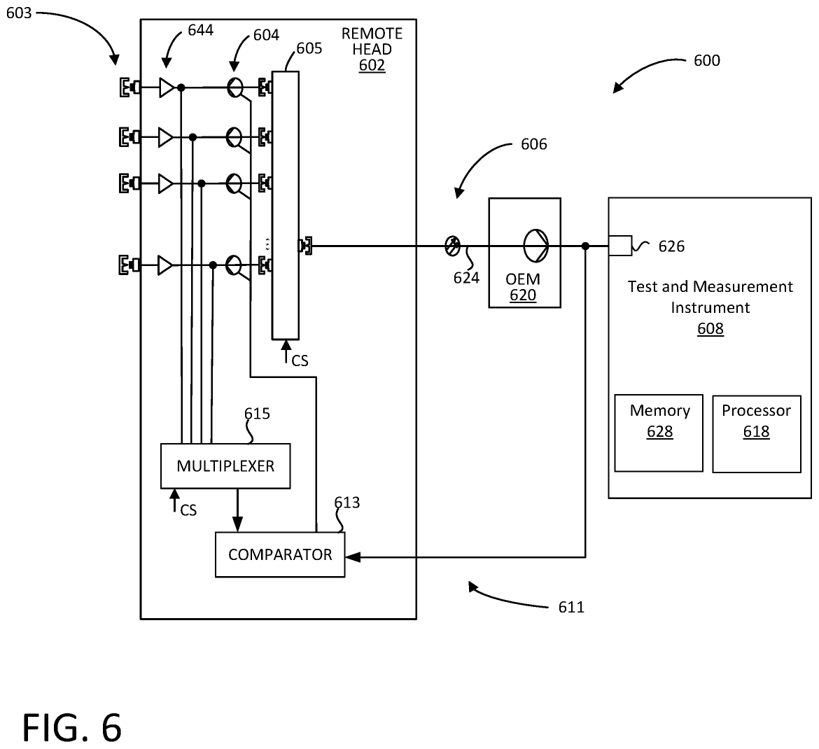

FIG. 6 is a block diagram of a test and measurement instrument 600 including a remote head 602 and feedforward compensation circuitry 611 that compensates for variations in optical interconnection circuitry 606 that may adversely affect characteristics of an electrical test signal provided on a test port 626 of a test and measurement instrument 608 according to some examples of the present disclosure. The remote head 602 includes a number of electrical input ports 603 configured to receive an electrical test signal from a DUT (not shown). Each electrical test signal on a port 603 is provided to a corresponding electrical-to-optical converter (EOM) 604, and a corresponding optical test signal generated by each EOM is supplied to respective optical input port of an optical switch or multiplexer 605. One the optical test signals form the EOMs 604 is selected by the optical multiplexer 605 in response to control signals CS and supplied on an output optical port of the multiplexer to the optical interconnection circuitry 606 coupled to the test and measurement instrument 608.

The optical interconnection circuitry 606 includes a fiber optic cable 624 and optical-to-electrical modulator (OEM) 620 in the embodiment of FIG. 6. The cable 624 and OEM 620 may undergo changes in operating characteristics during operation of the system 600. For example, changes in temperature of the fiber optic cable 624 may result in a change in length of the cable that is significant at the small wavelengths of the optical test signals propagating over the cables. The compensation circuitry 611 compensates for such variations. The compensation circuitry 611 includes a comparator 613 that compares a low frequency or DC component of the electrical test signal output by the OEM 620 to the low frequency or DC component of the electrical test signal that is supplied to the corresponding EOM 604 in the test head 602. The electrical test signal supplied to the corresponding EOM 604 is supplied to one input of the comparator 613 through a multiplexer 615 in response to the control signals CS. The comparator 613 generates an output based on the comparison of the low frequency components of the two electrical test signals, and provides the output to bias inputs of the EOMs 604 to compensate for variations in the electrical test signal output by the OEM 620 due to variations in characteristics of the optical interconnection circuitry 606.

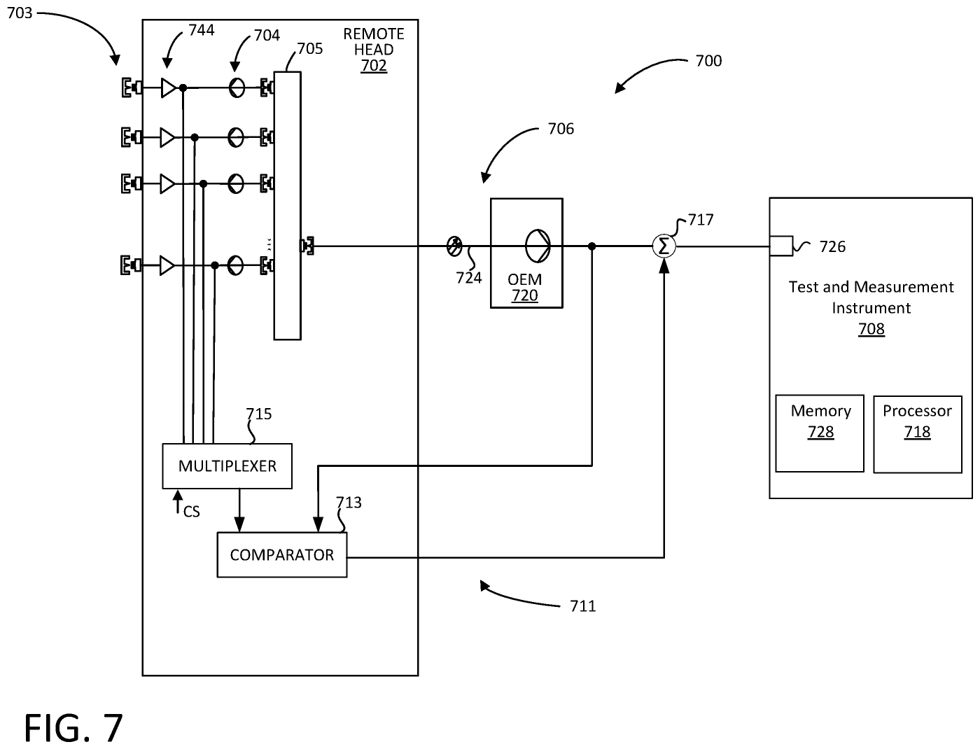

FIG. 7 is a block diagram of a test and measurement instrument 700 including a remote head 702 and feedback compensation circuitry 711 that compensates for variations in optical interconnection circuitry 706 that may adversely affect characteristics of an electrical test signal provided on a test port 726 of a test and measurement instrument 708 according to some examples of the present disclosure. The compensation circuitry 711 includes a comparator 713 that compares a low frequency or DC component of the electrical test signal output by the OEM 720 to the low frequency or DC component of the electrical test signal that is supplied to the corresponding EOM 704 in the test head 702. The electrical test signal supplied to the corresponding EOM 704 is supplied to one input of the comparator 713 through a multiplexer 715 in response to controls signals CS. The comparator 713 generates an output based on the comparison of the low frequency components of the two electrical test signals, and provides the output to an adder 717 that is coupled to the output of the OEM 720. In this way, the adder 717 adds a low frequency or DC component to the electrical test signal output by the OEM 720 to compensate for variations in the optical interconnection circuitry 706 that may occur during operation of the system 700, as was discussed above with reference to the system 600 of FIG. 6.

In the test and measurement systems 100-700, the components in these systems interconnecting the DUTs and the test and measurement instruments may receive power in different ways. The provision of power will now be discussed in more detail with reference to the test and measurement system of FIG. 1, but this discussion applies to the embodiments of FIGS. 2 and 3 as well. In some embodiments, the test and measurement instrument 108 may supply power over a suitable power line (not shown) to power components in the remote heads 102A, 102AB, as well as other components such as the OEM 120 and optical switch 112. In other embodiments, the remote heads 102A, 102B may be coupled to a power supply separate from the measurement instrument 108, such as one directly plugged into wall power. In yet other embodiments, the remote heads 102A, may be able to draw power from the DUTs 110A, 110B without affecting the integrity of the signals of the DUTs for testing. For example, a Universal Serial Bus (USB) transmits power as well as data over its lines and remote heads 102A, 102B may be able to use a small amount of power from the USB cables.

In yet further embodiments, the power needs of the remote heads 102A, 102B may be small enough that they can be satisfied by a battery (not shown), either rechargeable or replaceable, contained within each remote head. This may be possible with certain embodiments of the remote heads 102A, 102B where circuitry is embodied as an Application Specific Integrated Circuit (ASIC) or Micro-ElectroMechanical System (MEMS) switches. In other embodiments, the components contained in the remote heads 102A, 102B and the optical interconnection circuitry 106 may include multiple discrete components mounted to one or more Printed Circuit Board (PCBs).

As mentioned above, the control signals CS, RFCS may be supplied by the test and measurement instruments 108, 208A, 208B, 308, and in such embodiments a user or operator may operate the measurement instrument to select one of the signals from the DUTs 110A,B, 210A,B, and 310A,B for testing. The user may make the selection on a user interface (not shown) of the measurement instrument 108, 208A, 208B, 308, or may instruct the instrument using programmatic controls, such as using the PI programming interface available on measurement instruments from Tektronix, Inc. of Beaverton, Oregon. For example, the user may program the measurement instrument 160 to cause the differential output signals from the DUT 110A, for example, to be selected for testing, and then test desired parameters of the selected differential output signals at the test and measurement instrument 108 for a period of time. After the first testing period, a testing program on the instrument 108 causes the optical switch 112 to select a second differential output signal from the DUT 110B for testing. In this manner, all of the signals from the DUTs 110A, 110B, and possibly additional DUTs, may be scripted to be tested in sequence without any necessity of the user to physically change any cables between the DUTs and the measurement instrument 108. Instead, the switching to connect the desired signal of the DUTs 110A, 110B to the measurement instrument 108 is performed by controlling the optical switch 112. This operation of the optical switch 112 and RF switches 203A, 203B and 303A, 303B may in this way be programmatically controlled, and a user may program the system 100, 200, 300 to step through all of the connected signal lanes of all the DUTs 110A,B, 210A,B, and 310A,B without requiring any cables to be disconnected or rearranged. This can save hours of manual labor during a testing session.

Aspects of the disclosure may operate on particularly created hardware, firmware, digital signal processors, or on a specially programmed computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a computer readable storage medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or computer-readable storage media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the technologies disclosed herein are provided below. A configuration of the technologies may include any one or more, and any combination of, the examples described below.

Example 1 is a test and measurement system, including one or more remote heads, each of the one or more remote heads configured to be coupled to a respective device under test (DUT) to receive an electrical test signal from the DUT and each of the one or more remote heads including an electrical-to-optical modulator (EOM) configured to convert the received electrical test signal into an optical test signal, and optical interconnection circuitry coupled to receive the optical test signal from the EOM of the one or more remote heads, the optical interconnection circuitry configured, in response to control signals, to select one of the optical test signals and to convert the selected optical test signal into an electrical test signal to be supplied to a test port of a test and measurement instrument.

Example 2 is a test and measurement system according to Example 1, wherein the optical interconnection circuitry comprises an optical switch including a plurality of optical input ports, each optical input port coupled to receive the optical test signal from the EOM of one of one or more remote heads, the optical switch configured to select the optical test signal on one of the optical input ports responsive to the control signals and to provide the selected optical test signal on an optical output port, an optical waveguide coupled to the optical output port of the optical switch, an optical-to-electrical modulator (OEM) coupled to the optical waveguide to receive the selected optical test signal and convert the selected optical test signal into the electrical test signal to be supplied to the test port of the test and measurement instrument.

Example 3 is a test and measurement system according to Example 2, wherein the optical waveguide comprises a fiber optic cable.

Example 4 is a test and measurement system according to Example 2, wherein the OEM comprises a photodiode.

Example 5 is a test and measurement system according to Example 2, wherein each EOM comprises a Mach-Zehnder modulator.

Example 6 is a test and measurement system according to any of the preceding Examples, further comprising a pair of coaxial cables coupled between each DUT and the corresponding one of one or more remote heads, and in which the pair of coaxial cables provide a differential electrical test signal from the DUT to the corresponding remote head.

Example 7 is a test and measurement system according to Example 6, wherein each remote head further comprises a differential input amplifier configured to amplify the electrical test signal from the corresponding DUT.

Example 8 is a test and measurement system, including a pair of remote heads, each remote head configured to be coupled to a respective device under test (DUT) to receive one electrical test signal of an electrical differential test signal from the DUT and including an RF switch including a plurality of RF input ports, each RF input port coupled to receive a respective electrical test signal from one of the DUTs and configured, in response to control signals, to select one of RF input ports and provide the electrical test signal of the selected RF input port on an RF output port, and an electrical-to-optical modulator (EOM) configured to convert the electrical test signal on the RF output port into an optical test signal, and optical interconnection circuitry coupled to receive the optical test signals from the EOMs in the plurality of remote heads, and the optical interconnection circuitry configured to convert each of the optical test signals into a corresponding electrical test signal to be supplied to a test port of a test and measurement instrument.

Example 9 is a test and measurement system according to Example 8, wherein the optical interconnection circuitry comprises a pair of optical waveguides, each optical waveguide coupled to the EOM of one of the remote heads, and a pair of optical-to-electrical modulators (OEM), each OEM respectively coupled to one of the pair of optical waveguide to receive the corresponding optical test signal and convert the optical test signal into an electrical test signal to be supplied to the test port of the test and measurement instrument.

Example 10 is a test and measurement system according to Example 9, wherein the test and measurement system comprises separate first and second test and measurement instruments, and wherein the test and measurement system further comprises a synchronization circuit coupled to the first and second test and measurement instruments and configured to synchronize capture of electrical test signals received from the pair of OEMs on test ports of the separate first and second test and measurement instruments.

Example 11 is a test and measurement system according to Example 9, wherein the test and measurement system comprises a single test and measurement instrument including first and second test ports, each of the first and second test ports coupled to a corresponding one of the OEMs.

Example 12 is a test and measurement system according to Example 9, wherein the OEM comprises a photodiode.

Example 13 is a test and measurement system according to Example 9, wherein each optical waveguide comprises a fiber optic cable.

Example 14 is a test and measurement system according to Example 9, wherein each EOM comprises a Mach-Zehnder modulator.

Example 15 is a test and measurement system according to any preceding Example 8-14, further comprising a pair of coaxial cables coupled to each DUT, one coaxial cable of the pair of coaxial cables coupled to a respective RF input of the RF switch in one of the pair of remote heads and a second coaxial cable of the pair of coaxial cables coupled to a respective RF input of the RF switch in other one of the pair of remote heads.

Example 16 is a method including providing a plurality of electrical test signals to a remote head, selecting one of the plurality of electrical test signals to be provided to a test port of a test and measurement instrument, converting, in the remote head, the selected electrical test signal into a corresponding optical test signal, communicating the optical test signal over an optical waveguide to a test port of a test and measurement instrument, and converting, at the test port of the test and measurement instrument, the optical test signal into an electrical test signal to be supplied to a corresponding test channel of the test and measurement instrument.

Example 17 is a method according to Example 16, wherein selecting one of the plurality of electrical test signals to be provided to a test port of a test and measurement instrument comprises selecting one of the plurality of electrical test signals through an RF switch located in the remote head.

Example 18 is a method according to any of the preceding Example methods, wherein converting the selected electrical test signal into a corresponding optical test signal comprises modulating an optical carrier signal with the electrical test signal.

Example 19 is a method according to any of the preceding Example methods, wherein modulating the optical carrier signal with the electrical test signal comprises providing the electrical test signal to a Mach-Zehnder modulator (MZM).

Example 20 is a method according to any of the preceding Example methods, wherein selecting one of the plurality of electrical test signals to be provided to a test port of a test and measurement instrument is performed by an optical switch selecting the corresponding optical test signal to be communicated over the optical waveguide.

Example 21 is a remote head in a test and measurement system, including a plurality of electrical inputs each of which is configured to be coupled to a testing signal from one or more devices under test (DUTs) to receive an electrical test signal from the one or more DUTs, a plurality of electrical-to-optical modulators (EOMs) each respectfully coupled to one of the plurality of electrical inputs, each EOM configured to convert the received electrical test signal into an optical test signal, and an optical selection switch having a plurality of optical inputs each respectfully coupled to a respective one of the optical test signals from one of the EOMs, the optical selection switch structured to select one from the plurality of optical inputs as an output test signal.

Example 22 is a remote head according to Example 21, in which the plurality of EOMs and the optical selection switch is integrated in a monolithic photonic integrated circuit.

Example 23 is a remote head according to any of the preceding Examples 21-22, further comprising a second optical selection switch having a second plurality of optical inputs, each of the second plurality of optical inputs coupled to a testing signal from the one or more DUTs, the second optical selection switch structured to select one from the second plurality of optical inputs as a second output test signal.

Example 24 is a remote head of Example 23, in which the output test signal and the second output test signal are differential signals to each other.

Example 25 is a remote head according to any of the preceding Examples 21-24, further comprising an LF/DC correction loop.

Example 26 is a remote head according to Example 25, in which the LF/DC correction loop includes a multiplexer structured to select one of the plurality of electrical inputs, a comparator structured to compare the selected one of the electrical inputs to a electrical signal converted from the output test signal, and a signal modifier.

Example 27 is a remote head according to Example 26, in which the signal modifier is structured to control a bias input of the EOM.

Example 28 is a remote head according to Example 26, in which the signal modifier is structured to control the electrical signal converted from the output test signal.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that all features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Also, when reference is made in this application to a method having two or more defined steps or operations, the defined steps or operations can be carried out in any order or simultaneously, unless the context excludes those possibilities.

Although specific examples of the disclosure have been illustrated and described for purposes of illustration, it will be understood that various modifications may be made without departing from the spirit and scope of the disclosure. Accordingly, the disclosure should not be limited except as by the appended claims.

We claim:

1. A test and measurement system, comprising:
one or more remote heads, each of the one or more remote heads configured to be coupled to a respective device under test (DUT) to receive an electrical test signal from the DUT and each of the one or more remote heads including an electrical-to-optical modulator (EOM) configured to convert the received electrical test signal into an optical test signal; and
optical interconnection circuitry coupled to receive the optical test signal from the EOM of the one or more remote heads, the optical interconnection circuitry configured, in response to control signals, to select one of the optical test signals and to convert the selected optical test signal into an electrical test signal to be supplied to a test port of a test and measurement instrument.

2. The test and measurement system of claim 1, wherein the optical interconnection circuitry comprises:
an optical switch including a plurality of optical input ports, each optical input port coupled to receive the optical test signal from the EOM of one of one or more remote heads, the optical switch configured to select the optical test signal on one of the optical input ports responsive to the control signals and to provide the selected optical test signal on an optical output port;
an optical waveguide coupled to the optical output port of the optical switch; and
an optical-to-electrical modulator (OEM) coupled to the optical waveguide to receive the selected optical test signal and convert the selected optical test signal into the electrical test signal to be supplied to the test port of the test and measurement instrument.

3. The test and measurement system of claim 2, wherein the optical waveguide comprises a fiber optic cable.

4. The test and measurement system of claim 2, wherein the OEM comprises a photodiode.

5. The test and measurement system of claim 1, wherein each EOM comprises a Mach-Zehnder modulator.

6. The test and measurement system of claim 1, further comprising a pair of coaxial cables coupled between each DUT and the corresponding one of one or more remote heads, and in which the pair of coaxial cables provide a differential electrical test signal from the DUT to the corresponding remote head.

7. The test and measurement system of claim 6, wherein each remote head further comprises a differential input amplifier configured to amplify the electrical test signal from the corresponding DUT.

8. A test and measurement system, comprising:
a pair of remote heads, each remote head configured to be coupled to a respective device under test (DUT) to receive one electrical test signal of an electrical differential test signal from the DUT and including:
an RF switch including a plurality of RF input ports, each RF input port coupled to receive a respective electrical test signal from one of the DUTs and configured, in response to control signals, to select one of RF input ports and provide the electrical test signal of the selected RF input port on an RF output port; and
an electrical-to-optical modulator (EOM) configured to convert the electrical test signal on the RF output port into an optical test signal; and
optical interconnection circuitry coupled to receive the optical test signals from the EOMs in the plurality of remote heads, and the optical interconnection circuitry configured to convert each of the optical test signals into a corresponding electrical test signal to be supplied to a test port of a test and measurement instrument.

9. The test and measurement system of claim 8, wherein the optical interconnection circuitry comprises:
a pair of optical waveguides, each optical waveguide coupled to the EOM of one of the remote heads; and
a pair of optical-to-electrical modulators (OEM), each OEM respectively coupled to one of the pair of optical waveguide to receive the corresponding optical test signal and convert the optical test signal into an electrical test signal to be supplied to the test port of the test and measurement instrument.

10. The test and measurement system of claim 9, wherein the test and measurement system comprises separate first and second test and measurement instruments, and wherein the test and measurement system further comprises a synchronization circuit coupled to the first and second test and measurement instruments and configured to synchronize capture of electrical test signals received from the pair of OEMs on test ports of the separate first and second test and measurement instruments.

11. The test and measurement system of claim 9, wherein the test and measurement system comprises a single test and measurement instrument including first and second test ports, each of the first and second test ports coupled to a corresponding one of the OEMs.

12. The test and measurement system of claim 9, wherein the OEM comprises a photodiode.

13. The test and measurement system of claim 9, wherein each optical waveguide comprises a fiber optic cable.

14. The test and measurement system of claim 8, wherein each EOM comprises a Mach-Zehnder modulator.

15. The test and measurement system of claim 8, further comprising a pair of coaxial cables coupled to each DUT, one coaxial cable of the pair of coaxial cables coupled to a respective RF input of the RF switch in one of the pair of remote heads and a second coaxial cable of the pair of coaxial cables coupled to a respective RF input of the RF switch in other one of the pair of remote heads.

16. A method, comprising:
providing a plurality of electrical test signals to a remote head;
selecting one of the plurality of electrical test signals to be provided to a test port of a test and measurement instrument;
converting, in the remote head, the selected electrical test signal into a corresponding optical test signal;
communicating the optical test signal over an optical waveguide to a test port of a test and measurement instrument; and
converting, at the test port of the test and measurement instrument, the optical test signal into an electrical test signal to be supplied to a corresponding test channel of the test and measurement instrument.

17. The method of claim 16, wherein selecting one of the plurality of electrical test signals to be provided to a test port of a test and measurement instrument comprises selecting one of the plurality of electrical test signals through an RF switch located in the remote head.

18. The method of claim 16, wherein converting the selected electrical test signal into a corresponding optical test signal comprises modulating an optical carrier signal with the electrical test signal.

19. The method of claim 16, wherein modulating the optical carrier signal with the electrical test signal comprises providing the electrical test signal to a Mach-Zehnder modulator (MZM).

20. The method of claim 16, wherein selecting one of the plurality of electrical test signals to be provided to a test port of a test and measurement instrument is performed by an optical switch selecting the corresponding optical test signal to be communicated over the optical waveguide.

21. A remote head in a test and measurement system, comprising:
a plurality of electrical inputs each of which is configured to be coupled to a testing signal from one or more devices under test (DUTs) to receive an electrical test signal from the one or more DUTs;
a plurality of electrical-to-optical modulators (EOMs) each respectfully coupled to one of the plurality of electrical inputs, each EOM configured to convert the received electrical test signal into an optical test signal; and
an optical selection switch having a plurality of optical inputs each respectfully coupled to a respective one of the optical test signals from one of the EOMs, the optical selection switch structured to select one from the plurality of optical inputs as an output test signal.

22. The remote head of claim 21 in which the plurality of EOMs and the optical selection switch is integrated in a monolithic photonic integrated circuit.

23. The remote head of claim 21, further comprising: a second optical selection switch having a second plurality of optical inputs, each of the second plurality of optical inputs coupled to a testing signal from the one or more DUTs, the second optical selection switch structured to select one from the second plurality of optical inputs as a second output test signal.

24. The remote head of claim 23, in which the output test signal and the second output test signal are differential signals to each other.

25. The remote head of claim 21, further comprising an LF/DC correction loop.

26. The remote head of claim 25, in which the LF/DC correction loop comprises:
a multiplexer structured to select one of the plurality of electrical inputs;
a comparator structured to compare the selected one of the electrical inputs to a electrical signal converted from the output test signal; and
a signal modifier.

27. The remote head of claim 26, in which the signal modifier is structured to control a bias input of the EOM.

28. The remote head of claim 26, in which the signal modifier is structured to control the electrical signal converted from the output test signal.
